(19) United States
(12) Patent Application Publication
(10) Pub. No.: US 2009/0238998 A1
(43) Pub. Date: Sep. 24, 2009

(54) COAXIAL MICROWAVE ASSISTED DEPOSITION AND ETCH SYSTEMS

(75) Inventors: MICHAEL W. STOWELL, Loveland, CO (US); Nety Krishna, Sunnyvale, CA (US); Ralf Hofmann, Soquel, CA (US); Joe Griffith, San Jose, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/050,373

(22) Filed: Mar. 18, 2008

(51) Int. Cl. H05H 1/30; C23C 16/511; H01L 21/3065

(52) U.S. Cl. 427/575; 118/723 AN; 156/345.41

(57) ABSTRACT

Disclosed are systems for achieving improved film properties by introducing additional processing parameters, such as a movable position for the microwave source and pulsing power to the microwave source, and extending the operational ranges and processing windows with the assistance of the microwave source. A coaxial microwave antenna is used for radiating microwaves to assist in physical vapor deposition (PVD) or chemical vapor deposition (CVD) systems. The system may use a coaxial microwave antenna inside a processing chamber, with the antenna being movable between a substrate and a plasma source, such as a sputtering target, a planar capacitively generated plasma source, or an inductively coupled source. In a special case when only a microwave plasma source is present, the position of the microwave antenna is movable relative to a substrate. The coaxial microwave antenna adjacent to the plasma source can assist the ionization more homogeneously and allow substantially uniform deposition over large areas.

### BACKGROUND OF THE INVENTION

Glow discharge thin film deposition processes are extensively used for industrial applications and materials research, especially in creating new advanced materials. Although chemical vapor deposition (CVD) generally exhibits superior performance for deposition of material in trenches or holes, physical vapor deposition (PVD) is sometimes preferred because of its simplicity and lower cost. In PVD, magnetron sputtering is often preferred, as it may have a 100 times increase in deposition rate and a 100 times lower required discharge pressure than non-magnetron sputtering. Inert gases, especially argon, are usually used as sputtering agents because they do not react with target materials. When a negative voltage is applied to a target, positive ions, such as positively charged argon ions, hit the target and knock the atoms out. Secondary electrons are also ejected from the target surface. The magnetic field can trap the secondary electrons close to the target and the secondary electrons can result in more ionizing collisions with inert gases. This enhances the ionization of the plasma near the target and leads to a higher sputtering rate. It also means that the plasma can be sustained at a lower pressure. In conventional magnetron sputtering, a higher deposition rate may be achieved by increasing the power to the target or decreasing the distance from the target. However, a drawback is that magnetized plasma tends to have larger variations in plasma density, because the strength of the magnetic field significantly varies with distance. This non-homogeneity may cause complications for deposition of large areas. Also, conventional magnetron sputtering has relatively low deposition rate.

Unlike evaporative techniques, the energy of ions or atoms in PVD is comparable to the binding energy of typical surfaces. This would in turn help increase atom mobility and surface chemical reaction rates so that epitaxial growth may occur at reduced temperatures and synthesis of chemically metastable materials may be allowed. By using energetic atoms or ions, compound formation may also become easier. An even greater advantage can be achieved if the deposition material is ionized. In this case, the ions can be accelerated to desired energies and guided in direction by using electric or magnetic fields to control film intermixing, nano- or microscale modification of microstructure, and creation of metastable phases. Because of the interest in achieving a deposition flux in the form of ions rather than neutrals, several new ionized physical vapor deposition (IPVD) techniques have been developed to ionize the sputtered material and subsequently direct the ions toward the substrate using a plasma sheath that is generated by using an RF bias on the substrate.

The ionization of atoms requires a high density plasma, which makes it difficult for the deposition atoms to escape without being ionized by energetic electrons. Capacitively generated plasmas are usually very lightly ionized, resulting in low deposition rate. Denser plasma may be created using inductive discharges. Inductively coupled plasma may have a plasma density of 10¹¹ ions/cm³, approximately 100 times higher than comparable capacitively generated plasma. A typical inductive ionization PVD uses an inductively coupled plasma that is generated by using an internal coil with a 13.56-MHz RF source. A drawback with this technique is that ions with about 100 eV in energy bombard the coil, erode the coils and then generate sputtered contaminants that may adversely affect the deposition. Also, the high energy of the ions may cause damage to the substrate. Some improvement has been made by using an external-coil to resolve the problem associated with the internal ICP coil.

Another technique for increasing plasma density is to use a microwave frequency source. It is well known that at low frequencies, electromagnetic waves do not propagate in a plasma, but are instead reflected. However, at high frequencies such as typical microwave frequency, electromagnetic waves effectively allow direct heating of plasma electrons. As the microwaves input energy into the plasma, collisions can occur to ionize the plasma so that higher plasma density can be achieved. Typically, horns are used to inject the microwaves or a small stub antenna is placed in the vacuum chamber adjacent to the sputtering cathode for inputting the microwaves into the chamber. However, this technique does not provide a homogeneous assist to enhance plasma generation. It also does not provide enough plasma density to sustain its own discharge without the assistance of the sputtering cathode. Additionally, scale up of such systems for large area deposition is limited to a length on the order of 1 meter or less due to non-linearity.

There still remains a need for providing a high density homogeneous discharge adjacent to a sputtering cathode to increase localized ionization efficiency and to deposit films over large areas. There is also a need for lowering the energy of the ions to reduce surface damage to the substrate and thus reduce defect densities. There is a further need to affect the microstructure growth and deposition coverage such as gapfill in narrow trenches and to enhance film chemistry through controlling ion density and ion energy in the bulk plasma and near the substrate surface.

### BRIEF SUMMARY OF THE INVENTION

Embodiments of the present invention provide systems for achieving improved film properties by introducing additional processing parameters, such as a movable position for the microwave source and pulsing power to the microwave source, and extending the operational ranges and processing windows with the assistance of the microwave source. Embodiments of the invention use a coaxial microwave antenna for radiating microwaves to assist in physical vapor deposition (PVD) or chemical vapor deposition (CVD) systems. One aspect of the present invention is that the system uses a coaxial microwave antenna inside a processing chamber, with the antenna being movable between a substrate and a plasma source, such as a sputtering target, a planar capacitively generated plasma source, or an inductively coupled source. In a special case when only a microwave plasma source is present, the position of the microwave antenna is movable relative to a substrate. The coaxial microwave antenna adjacent to the plasma source can assist the ionization more homogeneously and allow substantially uniform deposition over large areas. Another aspect of the invention is that the antenna may be subjected to a pulsing power for increasing plasma efficiency over a continuous power.

In a first set of embodiments, a system comprises a processing chamber, a sputtering target, a substrate supporting member for holding a substrate in the processing chamber, a coaxial microwave antenna for radiating microwaves, and a gas supply system. The coaxial microwave antenna increases plasma density homogeneously adjacent to a sputtering target or cathode for PVD applications. A target is subjected to a DC voltage to cause them to act as cathodes if the target comprises metal, or subjected to an AC, RF or pulsing power if the target comprises dielectric material. The coaxial microwave plasma source may be linear or planar. A planar source may comprise a group of parallel coaxial microwave linear sources. A magnetron or a plurality of magnetrons may be added near the target to help confine the secondary electrons and enhance ionization through providing a magnetic field adjacent to the target surface. The gas supply system is configured to introduce inert gases into the processing chamber to act as sputtering agents.

In a second set of embodiments of the invention, a system for microwave and RF-assisted PECVD comprises a processing chamber, a substrate supporting member, a planar capacitively generated plasma source, a coaxial microwave antenna inside the chamber, and a gas supply system. The plasma is capacitively generated by using an RF power and further enhanced by using a secondary coaxial microwave source or antenna that may be linear or planar. The gas supply system is configured to introduce precursor gases and carrier gases into the processing chamber.

In a third set of embodiments of the invention, a system for microwave and ICP assisted-CVD comprises a processing chamber, a substrate supporting member, an inductive coil, a coaxial microwave antenna inside the chamber, and a gas supply system. The plasma is inductively generated by using an RF voltage and further enhanced by using the coaxial microwave antenna. The antenna may be linear or planar. Furthermore, the gas supply system is configured to introduce precursor gases and carrier gases into the processing chamber.

In a fourth set of the embodiments of the invention, a system for microwave plasma assisted-CVD comprises a processing chamber, a substrate supporting member, a coaxial microwave antenna inside the chamber, and a gas supply system. The antenna may be linear or planar. Again, the gas supply system is configured to introduce precursor gases and carrier gases into the processing chamber.

Embodiments of the invention also include a movable microwave antenna inside a processing chamber. In one specific embodiment of the invention, the antenna is near the target for increasing the plasma density of radical species and reducing energy broadening. In another specific embodiment of the invention, the antenna is approximately in the middle of the processing chamber for enhancing bulk plasma properties. In a third specific embodiment of the invention, the antenna is near the substrate to affect film properties such as density and edge coverage.

The potential areas of application by the present invention include solar cells (e.g. deposition of amorphous and microcrystalline photovoltaic layers with band gap controllability and increased deposition rates); plasma display devices (e.g. deposition of dielectric layers with energy savings and lower manufacturing cost); scratch resistant coatings (e.g. thin layers of organic and inorganic materials on polycarbonate for UV absorption and scratch resistance); advanced chip-packaging plasma cleaning and pretreatment (e.g. the advantages are zero static charge buildup and without UV radiation damage); semiconductors, alignment layers, barrier films, optical films, diamond like carbon and pure diamond films, where improved barriers and scratch resistance can be achieved by using the present invention.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings.

### BRIEF DESCRIPTION OF THE DRAWINGS

FIG. 1A is an exemplary simplified microwave-assisted sputtering and etching system.

FIG. 1B is an exemplary simplified microwave-assisted magnetron sputtering and etching system.

FIG. 2 is an exemplary simplified microwave and planar plasma-assisted PECVD deposition and etch system.

FIG. 3 is an exemplary simplified microwave and inductively coupled plasma-assisted CVD deposition and etch system.

FIG. 4 is an exemplary simplified microwave-assisted CVD deposition and etch system.

FIG. 5 is a flow chart for illustrating simplified deposition steps for forming a film on a substrate.

FIG. 6 illustrates the effect of pulsing frequency on the light signal from plasma.

FIG. 7A provides a simplified schematic of a planar plasma source consisting of 4 coaxial microwave linear sources.

FIG. 7B provides an optical image of a planar microwave source consisting of 8 parallel coaxial microwave plasma sources.

FIG. 8 shows the homogeneity of a coaxial microwave plasma linear source.

FIG. 9 is a graph demonstrating the saturation of continuous microwave plasma density versus microwave power.

FIG. 10 is a graph revealing the improved plasma efficiency in pulsing microwave power compared to continuous microwave power.

### DETAILED DESCRIPTION OF THE INVENTION

### 1. Overview of Microwave Assisted Deposition

Microwave plasma has been developed to achieve higher plasma densities (e.g. 10¹² ions/cm³) and higher deposition rates, as a result of improved power coupling and absorption at 2.45 GHz when compared to a typical radio frequency (RF) coupled plasma sources at 13.56 MHz. One drawback of the RF plasma is that a large portion of the input power is dropped across the plasma sheath (dark space). By using microwave plasma, a narrow plasma sheath is formed and more power can be absorbed by the plasma for creation of radical and ion species, which increases the plasma density and reduces collision broadening of the ion energy distribution to achieve a narrow energy distribution.

Microwave plasma also has other advantages such as lower ion energies with a narrow energy distribution. For instance, microwave plasma may have low ion energy of 1-25 eV, which leads to lower damage when compared to RF plasma. In contrast, standard planar discharge would result in high ion energy of 100 eV with a broader distribution in ion energy, which would lead to higher damage, as the ion energy exceeds the binding energy for most materials of interest. This ultimately inhibits the formation of high quality crystalline thin films through introduction of intrinsic defects. With low ion energy and narrow energy distribution, microwave plasma helps in surface modification and improves coating properties.

In addition, a lower substrate temperature (e.g. lower than 200° C., for instance at 100° C.) is achieved, as a result of increased plasma density at lower ion energy with narrow energy distribution. Such a lower temperature allows better microcrystalline growth in kinetically limited conditions. Also, standard planar discharge without magnetron normally requires pressure greater than about 50 mtorr to maintain self-sustained discharge, as plasma becomes unstable at pressure lower than about 50 mtorr. The microwave plasma technology described herein allows the pressure to range from about 10⁻⁶ torr to 1 atmospheric pressure. The processing windows such as temperature and pressure are therefore extended by using a microwave source.

In the past, one drawback associated with microwave source technology in the vacuum coating industry was the difficulty in maintaining homogeneity during the scale up from small wafer processing to very large area processing. Microwave reactor designs in accordance with embodiments of the invention address these problems. Arrays of coaxial plasma linear sources have been developed to deposit substantially uniform coatings of ultra large area (greater than 1 m²) at high deposition rate to form dense and thick films (e.g. 5-10 μm thick).

An advanced pulsing technique has been developed to control the microwave power for generating plasma, and thus to control the plasma density and plasma temperature. This advanced pulsing technique may reduce the thermal load disposed over the substrate, as the average power may remain low. This feature is relevant when the substrate has a low melting point or a low glass transition temperature, such as in the case of a polymer substrate. The advanced pulsing technique allows high power pulsing into plasma with off times in between pulses, which reduces the need for continuous heating of the substrate. Another aspect of the pulsing technique is significant improvement in plasma efficiency compared to continuous microwave power.

### 2. Sputtering Cathode and Conditions for Sustaining Plasma Discharge

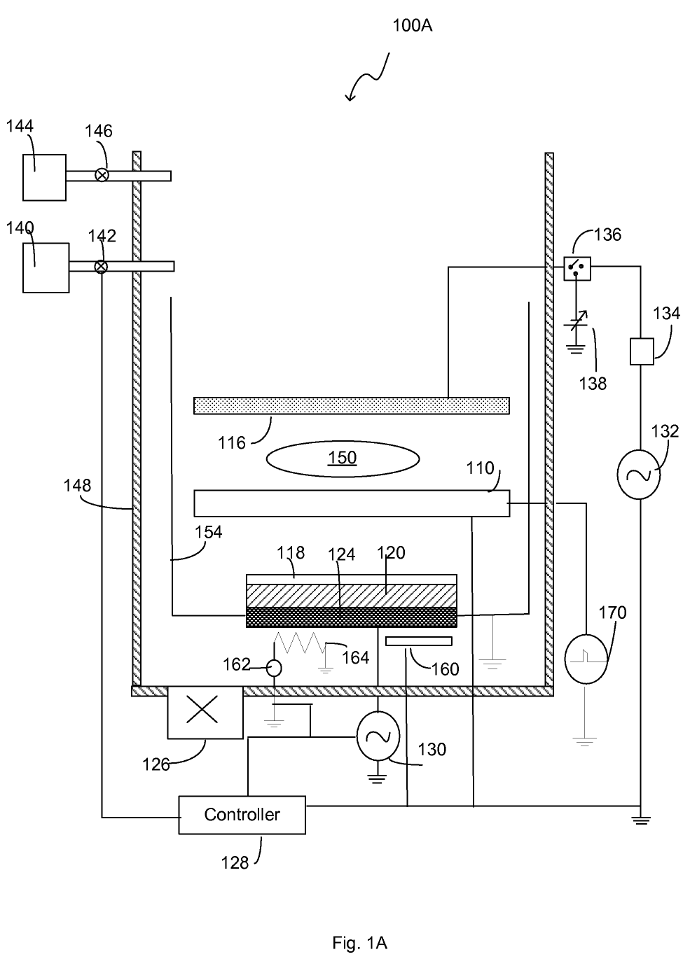

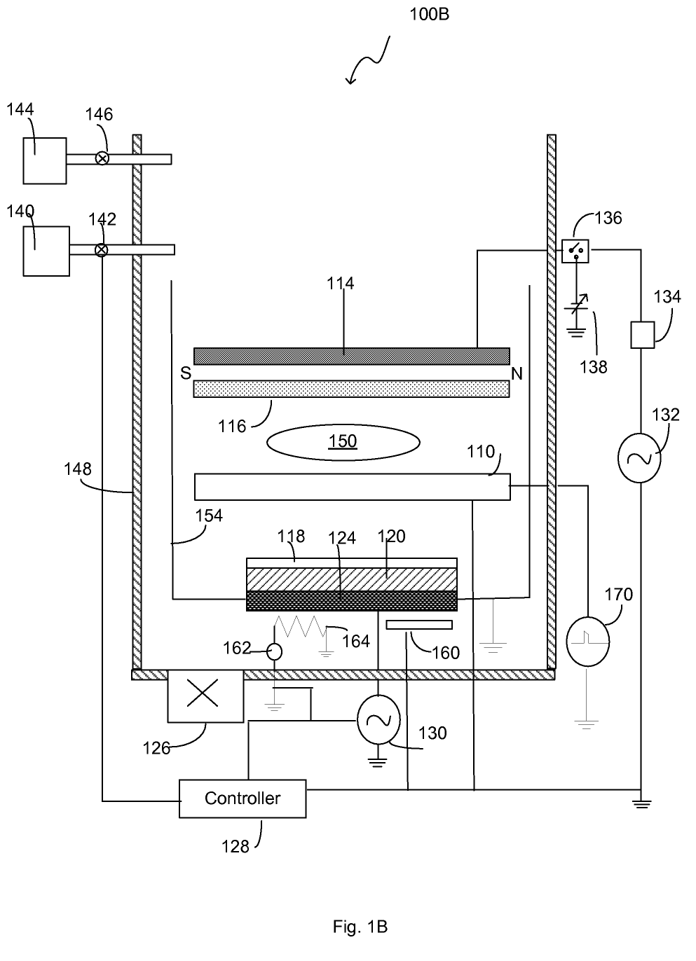

Referring to FIGS. 1A and 1B, target 116 in sputtering system 100A and magnetron sputtering system 100B may be made of metal, dielectric material, or semiconductor. For a metal target such as aluminum, copper, titanium, or tantalum, a DC voltage may be applied to the target to make the target a cathode and the substrate an anode. The DC voltage would help accelerate free electrons. The free electrons collide with sputtering agents such as argon (Ar) atoms from argon gas to cause excitation and ionization of Ar atoms. The excitation of Ar results in gas glow. The ionization of Ar generates Ar⁺and secondary electrons. The secondary electrons repeat the excitation and ionization process to sustain the plasma discharge.

Near the cathode, positive charges build up as the electrons move much faster than ions due to their smaller mass. Therefore, fewer electrons collide with Ar so that fewer collisions with the high energy electrons result in mostly ionization rather than excitation. A Crookes dark space is formed near the cathode. Positive ions entering the dark space are accelerated toward the cathode or target and bombard the target so that atoms are knocked out from the target and then transported to the substrate and also secondary electrons are generated to sustain the plasma discharge. If the distance between cathode to anode is less than the dark space, few excitations occur and discharge can not be sustained. On the other hand, if the Ar pressure in a chamber is too low, there would be a larger electron mean-free path such that secondary electrons would reach anode before colliding with Ar atoms. In this case, discharge also can not be sustained. Therefore, a condition for sustaining the plasma is

L*P>0.5 (cm-torr)

where L is the electrode spacing and P is the chamber pressure. For instance, if a spacing between the target and the substrate is 10 cm, P should be greater than 50 mtorr.

The mean-free path λ of an atom in a gas is given by:

λ(cm)˜5×10⁻³/P (torr)

If P is 50 mtorr, λis about 0.1 cm. This means that sputtered atoms or ions typically have hundreds of collisions before reaching the substrate. This reduces the deposition rate significantly. In fact, the sputtering rate R is inversely proportional to the chamber pressure and the spacing between target and substrate. Therefore, lowering required chamber pressure for sustaining discharge increases deposition rate.

With a secondary microwave source near the sputtering cathode, the sputtering system allows the cathode to run at a lower pressure, lower voltage and possibly higher deposition rate. By decreasing operational voltage, atoms or ions have lower energy so that damage to the substrate is reduced. With the high plasma density and lower energy plasma from microwave assist, high deposition rate can be achieved along with lower damage to the substrate.

Referring to FIGS. 1A and 1B again, the target 116 in the sputtering system 100A and magnetron sputtering system 100B may be made of dielectric material, such as silicon oxide, aluminum oxide, or titanium oxide. The target 106 may be subjected to AC, RF, or pulsing power to accelerate free electrons.

### 3. Exemplary Microwave Assisted-PVD

FIG. 1B depicts a simplified schematic, cross-sectional diagram of a physical vapor deposition (PVD) magnetron sputtering system 100B assisted with a coaxial microwave antenna 110. The system may be used to practice embodiments of the invention. The system 100B includes a vacuum chamber 148, a target 116, a magnetron 114, a coaxial microwave antenna 110 positioned below the target 116, a substrate supporting member 124, a vacuum pump system 126, a controller 128, gas supply systems 140, 144, and a shield 154 for protecting the chamber walls and the sides of the substrate supporting member from sputtering deposition. The following references, i.e. U.S. Pat. No. 6,620,296 B2, U.S. Patent Application Pub. No. US 2007/0045103 A1, and U.S. Patent Application Pub. No. US2003/0209422 A1, are cited here for exemplary PVD magnetron sputtering systems used by Applied Materials and others and are incorporated herein by reference for all purposes.

Target 116 is a material to be deposited on a substrate 120 to form a film 118. The target 116 may comprise dielectric materials or metals. The target is typically structured for removable insertion into the corresponding PVD magnetron sputtering system 100B. Targets 116 are periodically replaced with new targets given that the PVD process erodes away the target material.

Both DC power supply 138 and the high frequency or pulsing power supply 132 are coupled through a device to the target 116. The device may be a switch 136. The switch 136 selects power from either the DC power supply 138 or the power from the AC, RF or pulsing power supply 132. A relatively negative voltage source 138 provides a DC cathode voltage of a few hundred volts. The specific cathode voltage varies with design. As the target can act as a source of negatively charged particles, the target may also be referred to as the cathode. Those skilled in the art will realize that there may be many ways for switching DC and RF power that would fulfill the function. Furthermore, in some embodiments, it may be advantageous to have both DC and RF power coupled to the target simultaneously.

The sputtering rate can be significantly increased by using a magnetron as illustrated in FIG. 1B compared to FIG. 1A without a magnetron. A magnetron 114 is generally positioned near target 116, for example above the target in FIG. 1B. The magnetron 114 has opposed magnets (S, N) for creating a magnetic field within the chamber nearby the magnetron 114. The magnetic field confines secondary electrons, so that for charge neutrality, the ion density would increase to form a high density plasma 150 within the chamber adjacent to the magnetron 114. The magnetron 114 may have variable sizes, positions, and a number of shapes for controlling the degree of plasma ionization. The magnetron 114 may have any shape, among others, an oval, a triangle, a circle, and a flattened kidney shape. The magnetron 114 may also have an unbalanced design, i.e. the magnetic flux of the.outer pole may be greater than the magnetic flux produced by the inner pole. A few references are provided here, e.g. U.S. Pat. No. 5,242,566 for a flattened kidney shape magnetron, U.S. Pat. No. 6,306,265 for a triangularly shaped outer pole, and U.S. Pat. No. 6,290,825 for different shapes of magnetron. Each of the foregoing patents is incorporated herein by reference for all purposes.

The coaxial microwave antenna 110 is located inside the chamber 148 between the target 116 and substrate 120. The position of the antenna 110 may be adjusted by using a controller 128. When the antenna 110 is near the target 116, the microwaves radiated from the antenna 110 help increase plasma density of radicals and ions and reduce energy broadening. On the other hand, when the antenna 110 is near the substrate 120, the microwaves help enhance bias effects of the substrate 120 to affect film properties such as density and edge coverage. While the antenna 110 may be located approximately in the middle of the chamber 148 between the target 116 and the substrate 120, the microwaves enhance bulk plasma properties.

The microwaves input energy into the plasma and the plasma is heated to enhance ionization and thus increase plasma density. The coaxial microwave antenna 110 may comprise a plurality of parallel coaxial antennas. The length of antenna 110 may be up to 3 m in some embodiments. One of the advantages of the coaxial microwave antenna 110 is to provide a homogeneous discharge adjacent to sputtering cathode or target 116. This allows substantially uniform deposition of a large area over substrate 120. The antenna 110 may be subjected to a pulsing power 170 or continuous power (not shown).

For the purpose of controlling the deposition of sputtered layer 118 on substrate 120, the substrate 120 may be biased by an RF power 130 coupled to the substrate supporting member 124 which is provided centrally below and spaced apart from the target 116, usually within the interior of the shield 154. The bias power may have a typical frequency of 13.56 MHz, or more generally between 400 kHz to about 500 MHz. The supporting member is electrically conductive and is generally coupled to ground or to another relatively positive reference voltage so as to define a further electrical field between the target 116 and the supporting member 124. The substrate 120 may be a wafer, such as a silicon wafer, or a polymer substrate. The substrate 120 may be heated or cooled during sputtering, as a particular application requires. A power supply 162 may provide current to a resistive heater 164 embedded in the substrate supporting member 124, commonly referred to as a pedestal, to thereby heat the substrate 120. A controllable chiller 160 may circulate chilled water or other coolants to a cooling channel formed in the pedestal. It is desirable that the deposition of film 118 be uniform across the entire top surface of the substrate 120.

Vacuum pump 126 can pump the chamber 148 to a very low base pressure in the range of 10⁻⁸ torr. A first gas source 140 connected to the chamber 148 through a mass flow controller 142 supplies inert gases such as argon (Ar), helium (He), xenon (Xe), and/or combinations thereof. A second gas source 144 supplies reactive gas, such as nitrogen (N₂) to the chamber 148 through a mass flow controller 146. The gases may be flowed into the chamber near the top of the chamber as illustrated in FIG. 1B above the antenna 110, magnetron 114, and target 116, or in the middle of the chamber (not shown) between the substrate 120 and target 116. The pressure of the sputtering gases inside the chamber is typically maintained between 0.2 mtorr and 100 mtorr.

A microprocessor controller 128 controls the position of the microwave antenna 110, a pulsing power or continuous power supply 170 for microwave, mass flow controller 142, a high frequency power supply 132, a DC power supply 138, a bias power supply 130, a resistive heater 164 and a chiller 160. The controller 128 may include, for example, a memory such as random access memory, read only memory, a hard disk drive, a floppy disk drive, or any other form of digital storage, local or remote, and a card rack coupled to a general purpose computer processor (CPU). The controller operates under the control of a computer program stored on the hard disk or through other computer programs, such as stored on a removable disk. The computer program dictates, for example, the timing, mixture of gases, pulsing or continuous power to the microwave antenna, DC or RF power applied on targets, biased RF power for substrate, substrate temperature, and other parameters of a particular process.

### 4. Exemplary Microwave and RF Plasma-Assisted CVD

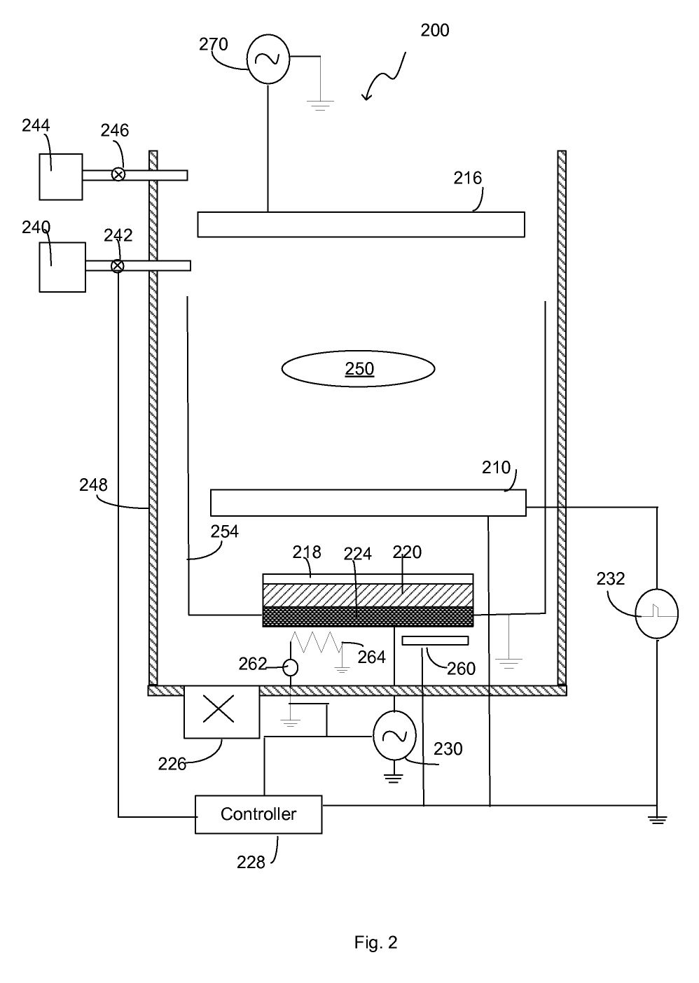

For depositing thick films such as 5-10 μm, the RF assisted PECVD method yields a very low deposition rate. Hence, a secondary microwave source is needed to increase plasma density and thus deposition rate. FIG. 2 is a simplified microwave and planar plasma-assisted PECVD system 200. It is very similar to the system 100A and 100B shown in FIGS. 1A and 1B, except the plasma source is not a sputtering target, but instead is a capacitively generated plasma source. The system 200 comprises a processing chamber 248, a planar plasma source 216, an antenna 210 inside the chamber between the planar plasma source 216 and the substrate 220, a substrate 220 on a substrate supporting member 224, gas delivery systems 244 and 240 with valves 246 and 242, a vacuum pump system 226, a shield 254, and a controller 228. The substrate may be heated by a heater 264 controlled using a power supply 262. The substrate may also be cooled by using a chiller 260. The substrate supporting member 224 is electrically conductive and may be biased by an RF power 230. The planar plasma source 216 is subjected to an RF power 270. A plasma 250 is formed inside the chamber 248 within the shield 254. Again, the position of the antenna 210 may be adjusted by the controller 228. The antenna 210 is a coaxial microwave plasma source and is subjected to a pulsing power 232 or continuous power (not shown). The gas delivery systems 244 and 240 provide the essential material sources for forming films 218 on the substrate 220.

### 5. Exemplary Microwave and Inductively Coupled Plasma-Assisted CVD

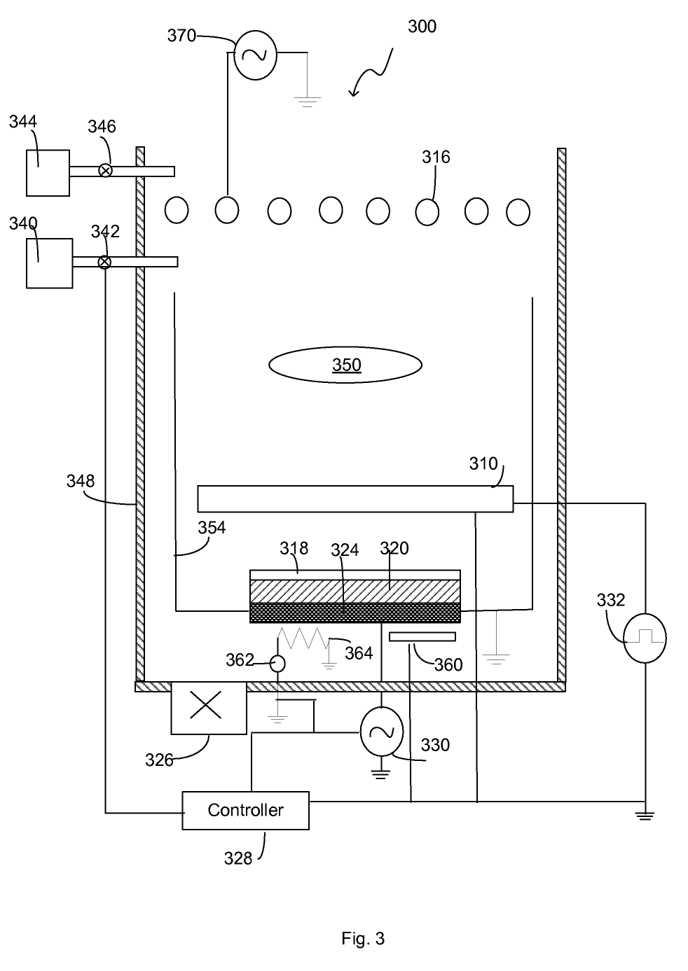

FIG. 3 illustrates a simplified microwave and ICP assisted deposition and etching system 300. Again, the system 300 is very similar to the systems 100A and 100B shown in FIGS. 1A and 1B, except the plasma source is not a sputtering target, but an inductively coupled plasma (ICP) coil 316. The system 300 comprises a processing chamber 348, an inductively coupled plasma source 316, an antenna 310 inside the chamber between the inductively coupled plasma source 316 and the substrate 320, a substrate 320 on a substrate supporting member 324, gas delivery systems 344 and 340 with valves 346 and 342, a vacuum pump system 326, a shield 354, and a controller 328. The substrate may be heated by a heater 364 controlled using a power supply 362. The substrate may also be cooled by using a chiller 360. The substrate supporting member 324 is electrically conductive and may be biased by an RF power 330. The inductively coupled plasma source 316 is subjected to an RF power 370. A plasma 350 is formed inside the chamber within the shield 354. Again, the position of the antenna 310 may be adjusted by the controller 328. The antenna 310 is a coaxial microwave plasma source and is subjected to a pulsing power 332 or a continuous power (not shown). The gas delivery systems 344 and 340 provide the essential material sources for forming films 318 on the substrate 320.

The solenoidal coil 316 is subjected to an RF voltage 370. The current in the coil generates a magnetic field in the vertical direction. This time varying magnetic field creates a time varying azimuthal electric field wrapping around the axis of the solenoid. The azimuthal electric field induces a circumferential current in the plasma. The electrons are therefore accelerated to increase energy, which increases plasma density. The RF frequency, for example, 13.56 MHz is commonly used, but not limited to.

### 6. Exemplary Microwave Plasma-Assisted CVD

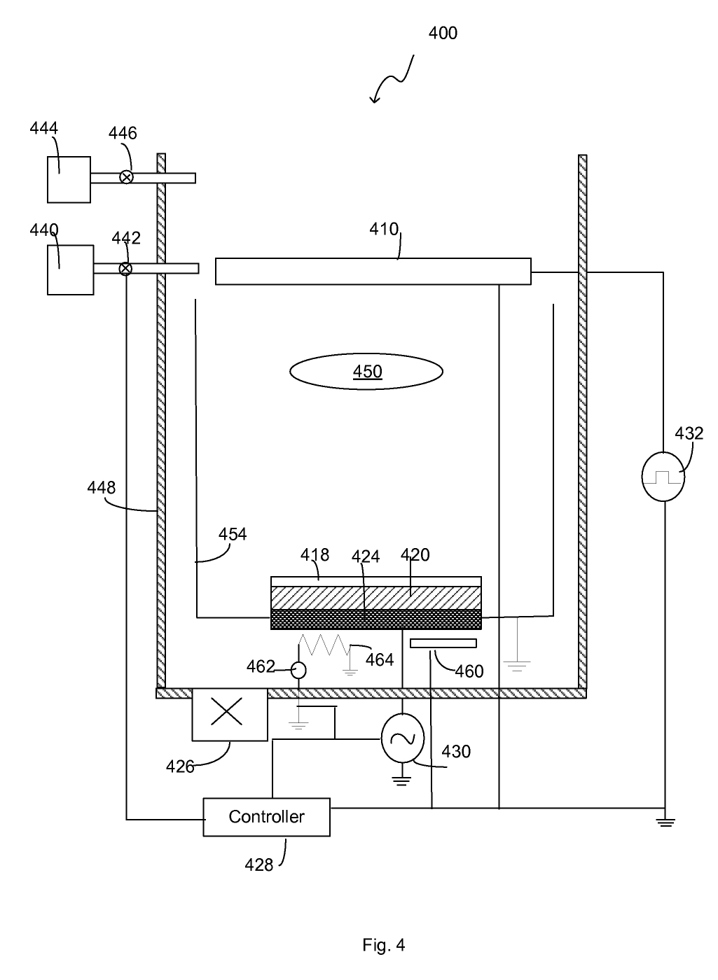

FIG. 4 is a simplified microwave-assisted CVD deposition and etch system 400. This system is different from systems 10A, 100B, 200 and 300, as only a microwave source is present and there are no other plasma sources such as sputtering target, planar plasma source or inductively coupled plasma source. The system 400 comprises a processing chamber 448, an antenna 410 inside the chamber above the substrate 420, a substrate 420 on a substrate supporting member 424, gas delivery systems 444 and 440 with valves 446 and 442, a vacuum pump system 426, a shield 454, and a controller 428. The substrate may be heated by a heater 464 controlled using a power supply 462. The substrate may also be cooled by using a chiller 460. The substrate supporting member 424 is electrically conductive and may be biased by an RF power 430. A plasma 450 is formed inside the chamber within the shield 454. Again, the position of the antenna 410 may be adjusted by the controller 428. The antenna 410 is a coaxial microwave plasma source and is subjected to a pulsing power 432 or a continuous power (not shown). The gas delivery systems 444 and 440 provide the essential material sources for forming films 418 on the substrate 420.

The systems 10A, 100B, 200, 300 and 400 may also be used for plasma etching or cleaning. For example, when nitrofluorinated etching gases such as NF₃ or carbofluorinated etching gases such as C₂F₆, C₃F₈ or CF₄ are introduced into the chamber, the unwanted materials deposited on components of the chamber may be removed by plasma etching or cleaning.

### 7. Exemplary Deposition Process

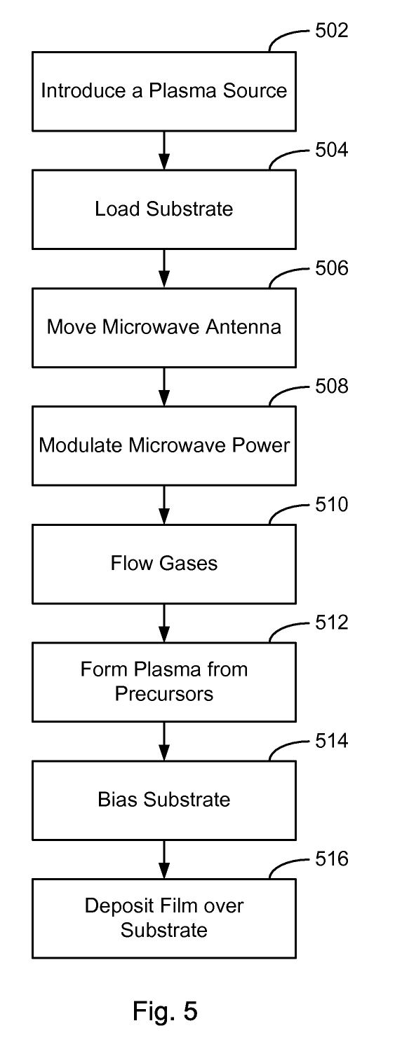

For purposes of illustration, FIG. 5 provides a flow diagram of a process that may be used to form a film on a substrate. The process begins with selecting a system by introducing a plasma source at block 502, such as a sputtering target, a capacitively generated plasma source, an inductively coupled plasma source, or with only microwave plasma source. Next, a substrate is loaded into a processing chamber as indicated at block 504. A microwave antenna is moved to a desired position at block 506, for example, near the target or substrate, depending upon the specific requirement. The microwave power is modulated at block 508, for instance, by a power supply using a pulsing power or a continuous power. Film deposition is initiated by flowing gases, such as sputtering agents, or reactive precusors, at block 510.

For deposition of SiO₂, such precursor gases may include a silicon-containing precursor such as hexamthyldisiloxane (HMDSO) and oxidizing precursor such as O₂. For deposition of SiOₓN_{y}, such precursor gases may include a silicon-containing precursor such as hexmethyldislanzane (HMDS), a nitrogen-containing precursor such as ammonia (NH₃), and an oxidizing precursor. For deposition of ZnO, such precursor gases may include a zinc-containing precursor such as diethylzinc (DEZ), and an oxidizing precursor such as oxygen (O₂), ozone (O₃) or mixtures thereof. The reactive precursors may flow through separate lines to prevent them from reacting prematurely before reaching the substrate. Alternatively, the reactive precursors may be mixed to flow through the same line.

The carrier gases may act as a sputtering agent. For example, the carrier gas may be provided with a flow of H₂ or with a flow of inert gas, including a flow of He or even a flow of a heavier inert gas such as Ar. The level of sputtering provided by the different carrier gases is inversely related to their atomic mass. Flow may sometimes be provided of multiple gases, such as by providing both a flow of H₂ and a flow of He, which mix in the processing chamber. Alternatively, multiple gases may sometimes be used to provide the carrier gases, such as when a flow of H₂/He is provided into the processing chamber.

As indicated at block 512, a plasma is formed from precursor gases by microwave at a frequency ranging from 1 GHz to 10 GHz, for example, commonly at 2.45 GHz (a wavelength of 12.24 cm). In addition, a higher frequency of 5.8 GHz is often used when power requirement is not as critical. The benefit of using a higher frequency source is that it has smaller size (about half size) of the lower frequency source of 2.45 GHz.

In some embodiments, the plasma may be a high-density plasma having an ion density that exceeds 10¹¹ ions/cm³. Also, in some instances the deposition characteristics may be affected by applying an electrical bias to the substrate at block 514. Application of such a bias causes the ionic species of the plasma to be attracted to the substrate, sometimes resulting in increased sputtering. The environment within the processing chamber may also be regulated in other ways in some embodiments, such as controlling the pressure within the processing chamber, controlling the flow rates of the precursor gases and where they enter the processing chamber, controlling the power used in generating the plasma, controlling the power used in biasing the substrate and the like. Under the conditions defined for processing a particular substrate, material is thus deposited over the substrate as indicated at block 516.

The inventors demonstrate an increase of deposition rate of approximately 3 times using pulsing microwaves in CVD. A SiO₂ film of about 5 μm thick and an area of approximately 800 mm by 200 mm is deposited on a substrate of about 1 m². The substrate is statically heated to about 280° C. The deposition time is only 5 minutes such that the deposition rate is roughly 1 μm/min. The SiO₂ film yields excellent optical transmittance and also has low contents of undesired organic materials.

### 8. Exemplary Planar Microwave Sources and Features

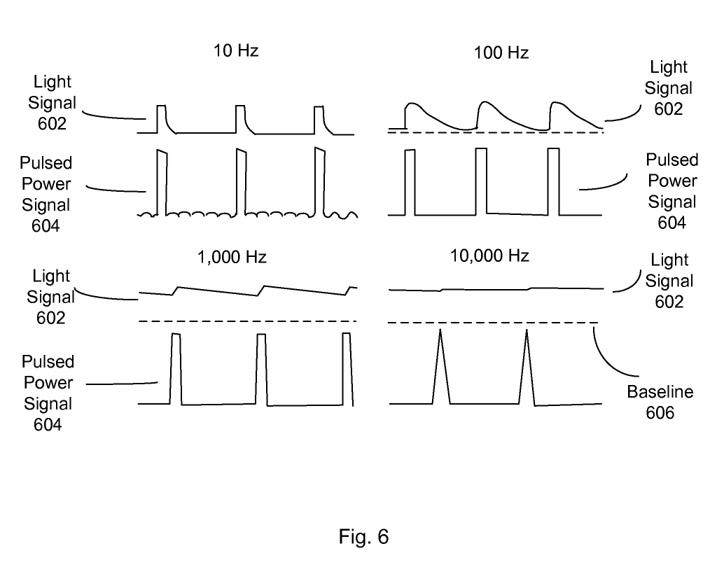

Pulsing frequency may affect the microwave pulsing power into plasma. FIG. 6 shows the frequency effect of the microwave pulsing power 604 on the light signal of plasma 602. The light signal of plasma 602 reflects the average radical concentration. As shown in FIG. 6, at a low pulsing frequency such as 10 Hz, in the event that all radicals are consumed, the light signal from plasma 602 decreases and extinguishes before the next power pulse comes in. As pulsing frequency increases to higher frequency such as 10,000 Hz, the average radical concentration is higher above the baseline 606 and becomes more stable.

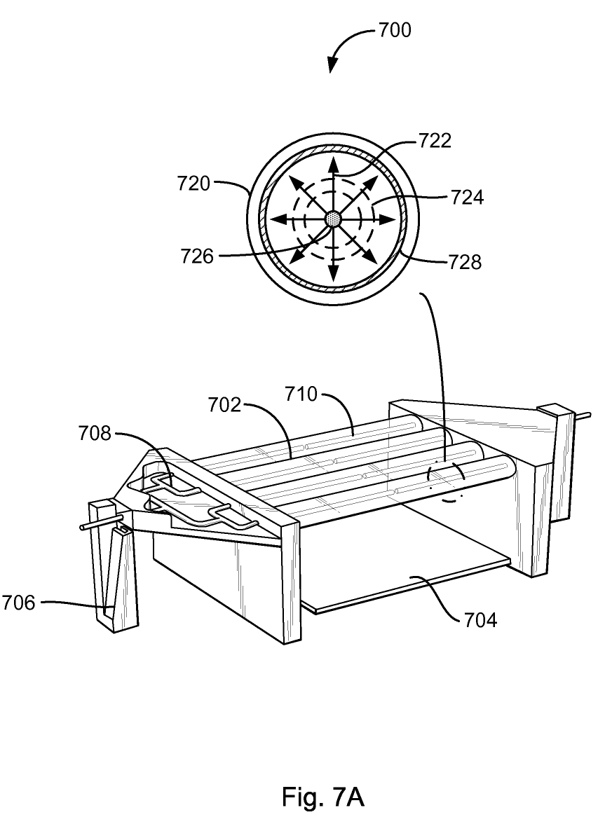

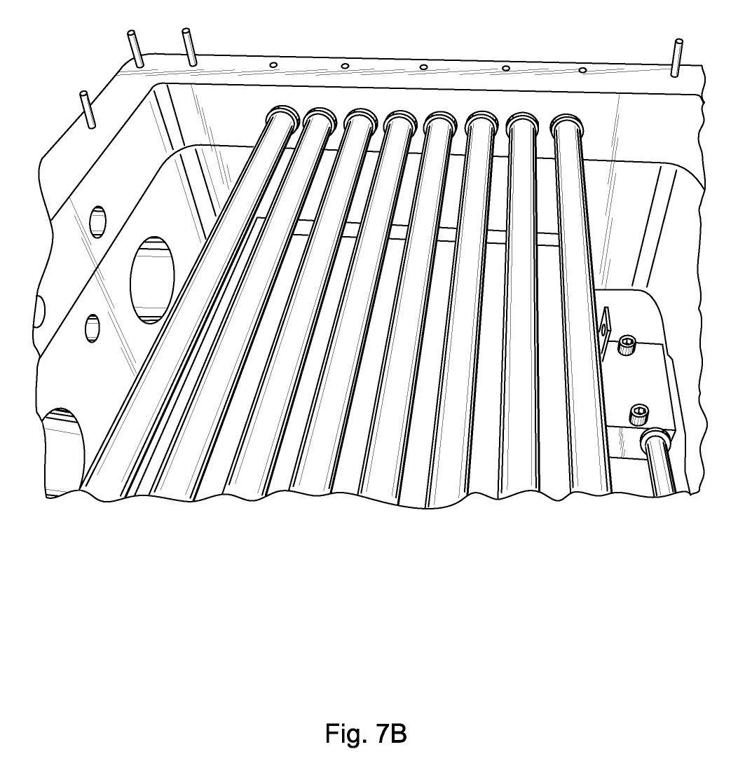

FIG. 7A shows a schematic of a simplified system including a planar coaxial microwave source 702 consisting of 4 coaxial microwave linear sources 710, a substrate 704, a Cascade coaxial power provider 708 and an impedance matched rectangular waveguide 706. In the coaxial microwave linear source 710, microwave power is radiated into the chamber in a transversal electromagnetic (TEM) wave mode. A tube replacing the outer conductor of the coaxial line is made of dielectric material such as quartz or alumina having high heat resistance and a low dielectric loss, which acts as the interface between the waveguide having atmospheric pressure and the vacuum chamber.

A cross sectional view of the coaxial microwave linear source 700 illustrates a conductor 726 for radiating microwave at a frequency of 2.45 GHz. The radial lines represent an electric field 722 and the circles represent a magnetic field 722. The microwaves propagates through the air to the dielectric layer 728 and then leak through the dielectric layer 728 to form an outer plasma conductor 720 outside the dielectric layer 728. Such a wave sustained near the coaxial microwave linear source is a surface wave. The microwave propagates along the linear line and goes through a high attenuation by converting electromagnetic energy into plasma energy. Another configuration is without quartz or alumina outside the microwave source (not shown).

FIG. 7B shows an optical image of a planar coaxial microwave source consisting of 8 parallel coaxial microwave linear sources. The length of each coaxial microwave linear source may be up to 3 m in some embodiments. Although the drawing shows that the planar coaxial microwave source is positioned horizontally, the planar coaxial microwave source may also be positioned vertically when a wafer is positioned vertically in a special embodiment (not shown). The benefit of such a vertical position of the wafer and microwave source is that any particles during processing may fall off the wafer positioned vertically because of gravity rather than collected on the wafer in a horizontal position. This may reduce the contamination during processing.

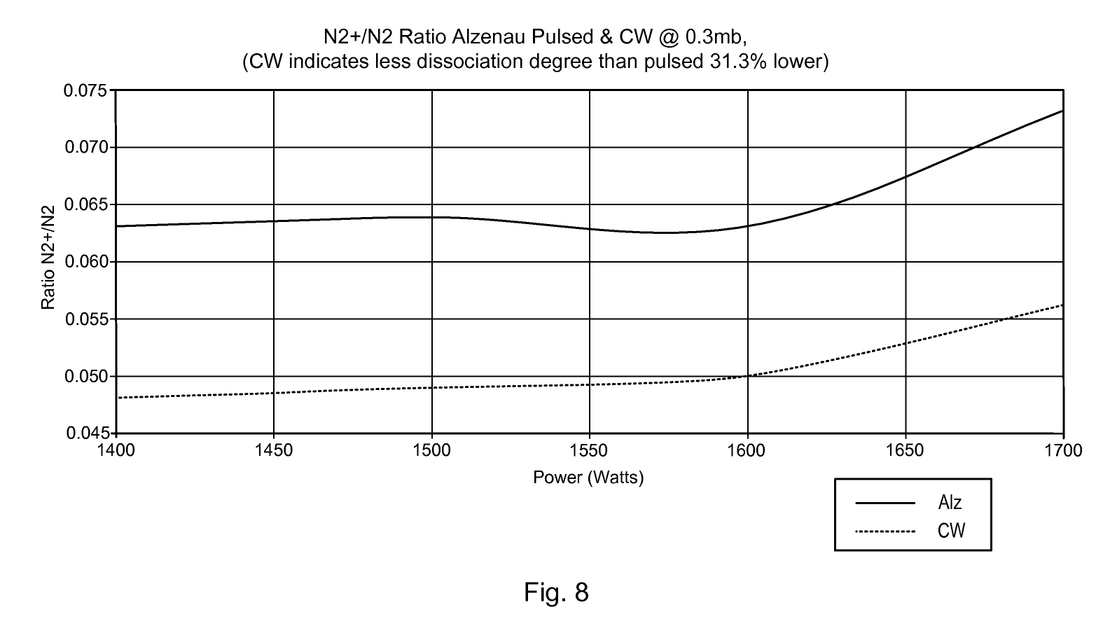

Typically, the microwave plasma linear uniformity is about ±15%. FIG. 8 shows the homogeneity of the coaxial microwave source obtained shown in FIG. 7B. The inventors have performed experiments to demonstrate that approximately ±1.5% of homogeneity over 1 m² can be achieved in dynamic array configuration and 2% over 1 m² in static array configurations. This homogeneity may be further improved to be below ±1% over large areas.

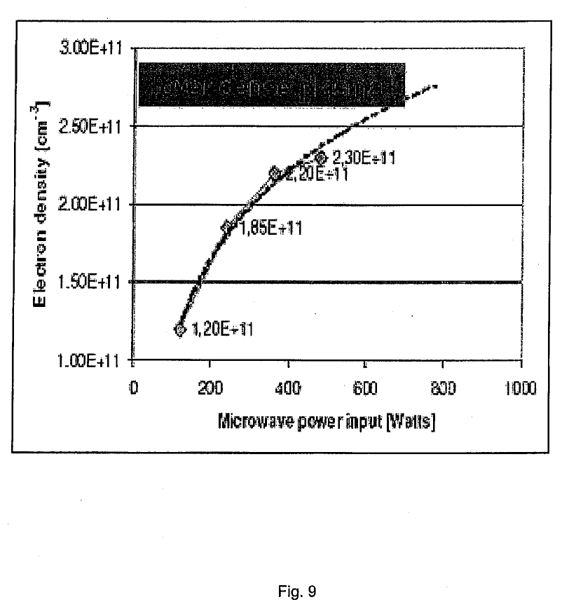

FIG. 9 shows the plasma density versus continuous microwave power. Note that when plasma density increases to above 2.2×10¹¹/cm³, the plasma density starts to saturate with increasing microwave power. The reason for this saturation is that the microwave radiation is reflected more once the plasma density becomes dense. Due to the limited power in available microwave sources, microwave plasma linear sources of any substantial length may not achieve optimal plasma conditions, i.e. very dense plasma. Pulsing microwave power allows for much higher peak energy into the antenna than continuous microwaves, such that the optimal plasma condition can be approached.

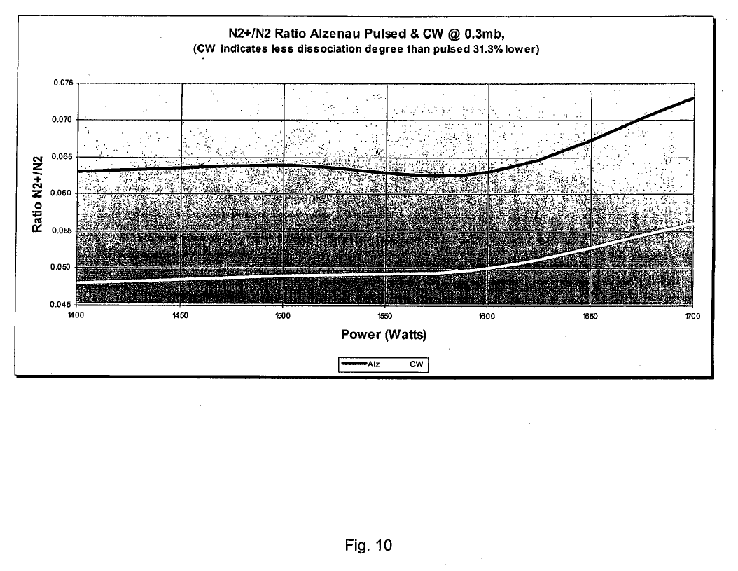

FIG. 10 shows a graph which illustrates the improved plasma efficiency of pulsing microwaves over continuous microwaves, assuming that the pulsing microwaves have the same average power as the continuous microwaves. Note that continuous microwaves result in less disassociation as measured by the ratio of nitrogen radical N₂+ over neutral N₂. A 31% increase in plasma efficiency can be achieved by using pulsing microwave power.

While the above is a complete description of specific embodiments of the present invention, various modifications, variations and alternatives may be employed. Moreover, other techniques for varying the parameters of deposition could be employed in conjunction with the coaxial microwave plasma source. Examples of the possible variations include but are not limited to different waveforms for pulsing power applied to the microwave antenna, various positions of the antenna, different shapes of magnetron, the DC, RF or pulsing power to the target, the microwave source, linear or planar, pulsing power or continuous power to the microwave source, the RF bias condition for the substrate, the temperature of the substrate, the pressure of deposition, and the flow rate of inert gases and the like.

Having described several embodiments, it will be recognized by those skilled in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

What is claimed is:

1. A microwave deposition and etch system comprising:
a processing chamber;
a substrate supporting member disposed within the processing chamber for holding a substrate;
a gas supply system for flowing gases into the processing chamber; and
a microwave antenna inside the chamber for radiating microwaves, the microwave antenna being movable relative to the substrate inside the processing chamber.

2. The microwave deposition and etch system of claim 1, wherein the microwave antenna comprises a coaxial microwave linear source or comprises a planar source having a plurality of parallel coaxial microwave linear sources.

3. The microwave deposition and etch system of claim 1, wherein a power source is adapted to provide a pulsing power or a continuous power to the microwave antenna.

4. The microwave deposition and etch system of claim 1, wherein the position of the microwave antenna is proximate the substrate.

5. The microwave deposition and etch system of claim 1, wherein a plasma source may be adopted to the microwave deposition and etch system.

6. The microwave deposition and etch system of claim 5, wherein the position of the microwave antenna is approximately in the middle of the chamber between the plasma source and the substrate.

7. The microwave deposition and etch system of claim 5, wherein the position of the microwave antenna is proximate the plasma source.

8. The microwave deposition and etch system of claim 5, wherein the plasma source comprises a sputtering target.

9. The microwave deposition and etch system of claim 8, wherein the sputtering target comprises metal, dielectric material or semiconductor.

10. The microwave deposition and etch system of claim 8, wherein a magnetron is located proximate the target to enhance plasma density.

11. The microwave deposition and etch system of claim 5, wherein the plasma source comprises a capacitively generated plasma source.

12. The microwave deposition and etch system of claim 5, wherein the plasma source comprises an inductively coupled source having an inductive coil subjected to an RF voltage providing an electric field for sustaining plasma.

13. A method for depositing a film on a substrate, the method comprising:
loading a substrate into a processing chamber by disposing the substrate over a substrate supporting member;
adjusting a position of a microwave antenna relative to the substrate;
generating microwaves with the microwave antenna;
modulating a power of the generated microwaves;
flowing gases into the processing chamber;
generating a plasma inside the processing chamber from the flowing gases with the generated microwaves; and
forming a layer on the substrate with the plasma.

14. The method for depositing a film on a substrate of claim 13, further comprising introducing a plasma source to the processing chamber.

15. The method for depositing a film on a substrate of claim 14, wherein the microwave antenna is configured to be movable between the substrate and the plasma source inside the processing chamber.

16. The method for depositing a film on a substrate of claim 14, wherein the plasma source comprises a sputtering target, a capacitively generated plasma source, or an inductively coupled plasma source.

17. The method for depositing a film on a substrate of claim 13, wherein the microwave antenna comprises a coaxial microwave linear source or comprises a planar source having a plurality of parallel coaxial microwave linear sources.

18. The method for depositing a film on a substrate of claim 13, wherein the microwave power is modulated by a pulsing or continuous power supply.

19. The method for depositing a film on a substrate of claim 13, wherein the substrate supporting member is biased by an RF power.
